(19) United States
(12) Patent Application Publication
(10) Pub. No.: US 2022/0069017 A1
(43) Pub. Date: Mar. 3, 2022

(54) DISPLAY PANEL AND METHOD FOR MANUFACTURING SAME, AND DISPLAY APPARATUS

(71) Applicants: Chengdu BOE Optoelectronics Technology Co., Ltd., Chengdu (CN); BOE Technology Group Co., Ltd., Beijing (CN)

(72) Inventors: Peng HOU, Beijing (CN); Jie LI, Beijing (CN); Huaisen REN, Beijing (CN); Yongzhan HAN, Beijing (CN); Tianquan TANG, Beijing (CN)

(21) Appl. No.: 17/405,982

(22) Filed: Aug. 18, 2021

(30) Foreign Application Priority Data
Sep. 2, 2020 (CN) 202010908922.8

(51) Int. Cl. H01L 27/32; H01L 51/52

(52) U.S. Cl. CPC H01L 27/322; H01L 27/3211; H01L 2227/323; H01L 51/5284; H01L 51/524; H01L 51/5271

(57) ABSTRACT

Provided is a display panel, including a substrate, an OLED device disposed on a side of the substrate, and a color film layer disposed on a side of the OLED device distal from the substrate. An orthographic projection of the color film layer onto the substrate at least covers an orthographic projection of a light-emitting layer of the OLED device onto the substrate. In a first environment, the color film layer is in a colorless and transparent state; in a second environment, at least partial region of the color film layer is in a colored and transparent state, and a color of the region in the colored and transparent state is the same as a light-emitting color of a target OLED device; and an ambient light luminance in the second environment is greater than an ambient light luminance in the first environment.

### CROSS-REFERENCE TO RELATED APPLICATION

This application is based on and claims priority to the Chinese Patent Application No. 202010908922.8, filed on Sep. 2, 2020 and entitled “MIRROR DISPLAY PANEL AND MIRROR DISPLAY APPARATUS”, the disclosure of which is herein incorporated by reference in its entirety.

### TECHNICAL FIELD

The present disclosure relates to the field of display technologies, and more particularly, to a display panel and a method for manufacturing same, and a display apparatus.

### BACKGROUND

An organic light-emitting diode (OLED) has the advantages of fast response, low working voltage, self-luminous property, light weight and thin thickness, wide applicable temperature range, flexible bending, high contrast, and simple manufacturing process, etc., and has been widely used in mobile phones, displays, mobile devices and other fields. With the increasing use demands of users and continuous development of display technologies, display apparatuses are becoming more and more diversified.

### SUMMARY

In one aspect, the embodiments of the present disclosure provide a display panel. The display panel include a substrate, an OLED device and a color film layer, wherein

the OLED device is disposed on a side of the substrate, and the color film layer is disposed on a side of the OLED device distal from the substrate;

an orthographic projection of the color film layer onto the substrate at least covers an orthographic projection of a light-emitting layer of the OLED device onto the substrate;

in a first environment, the color film layer is in a colorless and transparent state; in a second environment, at least partial region of the color film layer is in a colored and transparent state, and a color of the region in the colored and transparent state is the same as a light-emitting color of a target OLED device, the target OLED device being an OLED device covered by an orthographic projection of the region in the colored and transparent state onto the substrate; and an ambient light luminance in the second environment is greater than an ambient light luminance in the first environment.

Optionally, the color film layer satisfies at least one of the following conditions:

in the first environment, a light transmittance of the color film layer is greater than 85%; or

in the second environment, a transmittance of the color film layer to red light is greater than or equal to 50% a transmittance of the color film layer to green light is greater than or equal to 50%, and a transmittance of the color film layer to blue light is greater than or equal to 50%.

Optionally, the OLED device includes a red-light OLED device, a green-light OLED device and a blue-light OLED device;

the color film layer includes a first sub-layer, a second sub-layer and a third sub-layer, wherein the first sub-layer is disposed on a side of the red-light OLED device distal from the substrate; the second sub-layer is disposed on a side of the green-light OLED device distal from the substrate; and the third sub-layer is disposed on a side of the blue-light OLED device distal from the substrate; and

in the second environment, at least partial region of the first sub-layer is red, at least partial region of the second sub-layer is green, and at least partial region of the third sub-layer is blue.

Optionally, a material of the first sub-layer is a spironaphthopyran compound, a material of the second sub-layer is a spirooxazine derivative, and a material of the third sub-layer is a spiropyran compound.

Optionally, the display panel further includes a reflective layer and a first film layer, wherein

the reflective layer is disposed on a side of the OLED device distal from the substrate, and an orthographic projection of the reflective layer onto the substrate does not overlap an orthographic projection of the OLED device onto the substrate;

the first film layer is disposed on a side of the reflective layer distal from the substrate, and an orthographic projection of the first film layer onto the substrate covers an orthographic projection of the reflective layer onto the substrate; and

in the first environment, the first film layer is in a colorless and transparent state; and in the second environment, the first film layer is in a black state.

Optionally, the reflective layer is disposed on a side of the color film layer distal from the substrate.

Optionally, the reflective layer and the first film layer define a plurality of openings and the color film layer is disposed in the plurality of openings.

Optionally, the color film layer is disposed on a side of the reflective layer distal from the substrate, and the first film layer is disposed on a side of the color film layer distal from the reflective layer.

Optionally, a surface of the first film layer distal from the reflective layer is an arc-shaped convex surface.

Optionally, the orthographic projection of the reflective layer onto the substrate is disposed within the orthographic projection of the first film layer onto the substrate; and there is a gap between the orthographic projection of the reflective layer onto the substrate and the orthographic projection of the OLED device onto the substrate.

Optionally, the first film layer satisfies at least one of the following conditions:

in the first environment, a light transmittance of the first film layer is greater than 85%; or

in the second environment, a light transmittance of the first film layer at a wavelength of 380 nm to 780 nm is less than 2%.

Optionally, a material of the first film layer is AgCl.

Optionally, a material of the reflective layer is at least one of Al, Ag, or Mo.

Optionally, the display panel further includes an encapsulating layer, which is disposed on a side of the OLED device distal from the substrate and configured to encapsulate the OLED device; and the color film layer is disposed in at least one of the following arrangements:

on a surface of the encapsulating layer distal from the substrate; and

inside the encapsulating layer.

In another aspect, the embodiments of the present disclosure further provide a display apparatus. The display apparatus including a power supply component and a display panel, wherein the power supply component is configured to supply power to the display panel; the display panel includes a substrate, an OLED device and a color film layer;

the OLED device is disposed on a side of the substrate, and the color film layer is disposed on a side of the OLED device distal from the substrate;

an orthographic projection of the color film layer onto the substrate at least covers an orthographic projection of a light-emitting layer of the OLED device onto the substrate;

in a first environment, the color film layer is in a colorless and transparent state; in a second environment, at least partial region of the color film layer is in a colored and transparent state, and a color of the region in the colored and transparent state is the same as a light-emitting color of a target OLED device; the target OLED device being an OLED device covered by an orthographic projection of the region in the colored and transparent state onto the substrate; and an ambient light luminance in the second environment is greater than an ambient light luminance in the first environment.

Optionally, the display apparatus further includes a reflective layer and a first film layer, wherein

the reflective layer is disposed on a side of the OLED device distal from the substrate, and an orthographic projection of the reflective layer onto the substrate does not overlap an orthographic projection of the OLED device onto the substrate;

the first film layer is disposed on a side of the reflective layer distal from the substrate, and an orthographic projection of the first film layer onto the substrate covers an orthographic projection of the reflective layer onto the substrate; and

in the first environment, the first film layer is in a colorless and transparent state; and in the second environment, the first film layer is in a black state.

Optionally, the color film layer is disposed on a side of the reflective layer distal from the substrate, and the first film layer is disposed on a side of the color film layer distal from the reflective layer.

Optionally, a surface of the first film layer distal from the reflective layer is an arc-shaped convex surface.

In yet another aspect, the embodiments of the present disclosure provide a method for manufacturing a display panel. The method includes:

forming an OLED device on a side of a substrate; and

forming a color film layer on a side of the OLED device distal from the substrate, wherein an orthographic projection of the color film layer onto the substrate at least covers an orthographic projection of a light-emitting layer of the OLED device onto the substrate; in a first environment, the color film layer is in a colorless and transparent state; in a second environment, at least partial region of the color film layer is in a colored and transparent state, and a color of the region in the colored and transparent state is the same as a light-emitting color of a target OLED device, the target OLED device being an OLED device covered by an orthographic projection of the region in the colored and transparent state onto the substrate; and an ambient light luminance in the second environment is greater than an ambient light luminance in the first environment.

Optionally, the method further includes:

forming a reflective layer on a side of the OLED device distal from the substrate, wherein an orthographic projection of the reflective layer onto the substrate does not overlap an orthographic projection of the OLED device onto the substrate; and

forming a first film layer on a side of the reflective layer distal from the substrate, wherein an orthographic projection of the first film layer onto the substrate covers an orthographic projection of the reflective layer onto the substrate; in the first environment, the first film layer is in a colorless and transparent state; and in the second environment, the first film layer is in a black state.

### BRIEF DESCRIPTION OF THE DRAWINGS

FIG. 1 is a top view of a display panel provided by an embodiment of the present disclosure;

FIG. 2 is a sectional view of I-I in FIG. 1;

FIG. 3 is a schematic structural diagram of a display panel provided by an embodiment of the present disclosure;

FIG. 4 is a sectional view of II-II in FIG. 3;

FIG. 5 is a sectional view of a display panel provided by an embodiment of the present disclosure;

FIG. 6 is a sectional view of a display panel provided by an embodiment of the present disclosure;

FIG. 7 is a sectional view of a display panel provided by an embodiment of the present disclosure;

FIG. 8 is a sectional view of a display panel provided by an embodiment of the present disclosure;

FIG. 9 is a comparison diagram of structures of two display panels provided by the embodiments of the present disclosure;

FIG. 10 is a diagram showing the change of the light transmittance as wavelength changes in a first environment in an embodiment of the present disclosure;

FIG. 11 is a diagram showing the change of the light transmittance as wavelength changes in a second environment in an embodiment of the present disclosure;

FIG. 12 is a flowchart showing a method for manufacturing a display panel provided by an embodiment of the present disclosure; and

FIG. 13 is a flowchart showing a method for manufacturing a display panel provided by an embodiment of the present disclosure.

### DESCRIPTIONS OF THE REFERENCE SIGNS

100: substrate; 200: OLED device; 210: red-light OLED device; 220: green-light OLED device; 230: blue-light OLED device; 310: first film layer; 320: color film layer; 321: first sub-layer; 322: second sub-layer; 323: third sub-layer; 330: reflective layer; 400: encapsulating layer; 500: second film layer.

### DETAILED DESCRIPTION

Descriptions will be made in detail to the embodiments of the present disclosure, examples of which are illustrated in the accompanying drawings. Throughout the accompanying drawings, the same or similar reference signs represent the same or similar components or components with the same or similar functions. The embodiments described below with reference to the accompanying drawings are exemplary, and are only intended to explain the present disclosure, rather than to limit the present disclosure.

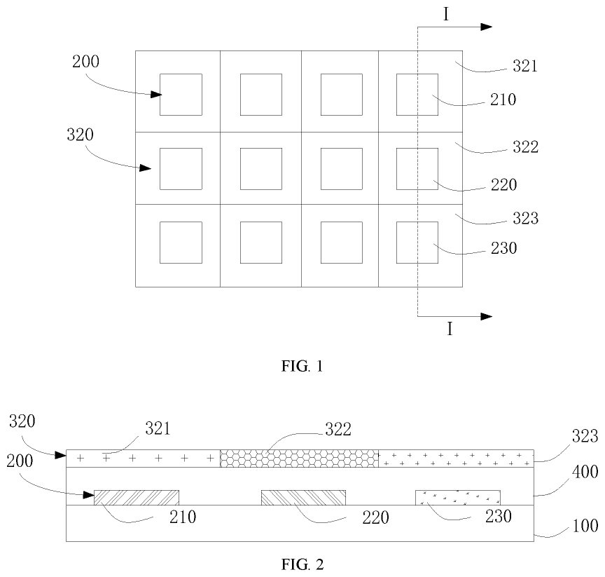

FIG. 1 is a schematic structural diagram of a display panel provided by an embodiment of the present disclosure. As shown in FIG. 1, the display panel includes a substrate 100, an OLED device 200 and a color film layer 320.

FIG. 2 is a sectional view of I-I in FIG. 1. As shown in FIG. 2, the OLED device 200 is disposed on a side of the substrate 100, and the color film layer 320 is disposed on a side of the OLED device 200 distal from the substrate 100. An orthographic projection of the color film layer 320 onto the substrate 100 at least covers an orthographic projection of a light-emitting layer of the OLED device 200 onto the substrate 100.

In a first environment, the color film layer 320 is in a colorless and transparent state; and in a second environment, at least partial region of the color film layer 320 is in a colored and transparent state, and a color of the region in the colored and transparent state is the same as a light-emitting color of a target OLED device. The target OLED device refers to the OLED device 200 covered by an orthographic projection of the region in the colored and transparent state onto the substrate 100. An ambient light luminance in the second environment is greater than an ambient light luminance in the first environment.

Exemplarily, the first environment is an indoor environment and the second environment is an outdoor environment.

In this case, when the display panel is in the first environment, the color film layer 320 is in a colorless and transparent state and the light transmittance is high. After the OLED device 200 is controlled to be powered on, the user can view the picture displayed on the display panel normally. In the second environment, the color film layer 320 is in a colored and transparent state. When light is emitted to the color film layer 320, the light having the same color as the region illuminated by the light can transmit through the color film layer 320, and the light having a different color from the region illuminated by the light will be absorbed by the color film layer 320. When the display panel performs display in the second environment and ambient light is emitted to the color film layer 320, only a part of the ambient light can transmit through the color film layer 320 depending on the color of the region illuminated by the ambient light, which reduces the intensity of the ambient light arriving at an electrode of the OLED device 200, thereby greatly reducing the reflection intensity of the ambient light by the display panel.

In addition, as in the color film layer 320, the color of the region in the colored and transparent state is the same as the light-emitting color of the target OLED device, when the OLED device 200 is powered on and emits light onto the color film layer 320, the region as illuminated has the same color as the light emitted by the target OLED device. Hence, the light emitted by the target OLED device can transmit through the color film layer 320. As such, the reflection intensity of the ambient light by the display panel is reduced, while the light emitted by the OLED device 200 can still transmit through the color film layer 320 normally. Therefore, in an environment with relatively strong ambient light, the user can still view a picture displayed on the display panel effortlessly.

In some embodiments of the present disclosure, there is no special requirement on the structure of the substrate 100, and a person skilled in the field can flexibly design the specific structure of the substrate 100 according to actual needs. In some examples, the substrate 100 includes a base substrate, a flexible substrate plate, a light-shielding layer, a buffer layer, an active layer, a gate insulating layer, a gate electrode, an interlayer dielectric layer, a source-drain electrode, a flattening layer or other structures.

As shown in FIG. 2, the OLED device 200 includes a red-light OLED device 210, a green-light OLED device 220 and a blue-light OLED device 230. Different OLED devices can emit light of different colors. The red-light OLED device 210, the green-light OLED device 220 and the blue-light OLED device 230 emit red light, green light and blue light respectively, such that the display panel can realize a function of displaying images with various colors.

The OLED device 200 includes an anode, a light-emitting layer, and a cathode. Holes are transported from the anode to the light-emitting layer, electrons are transported from the cathode to the light-emitting layer, and then the holes and the electrons are compounded in the light-emitting layer to realize a light-emitting function. The OLED device may further include a hole injection layer, a hole transport layer, an electron block layer, a hole block layer, an electron transport layer, and an electron injection layer, etc., so as to improve the overall performance of the OLED device.

As shown in FIG. 2, the color film layer 320 includes a first sub-layer 321, a second sub-layer 322 and a third sub-layer 323. The first sub-layer 321, the second sub-layer 322 and the third sub-layer 323 are arranged in a one-to-one correspondence with the red-light OLED device 210, the green-light OLED device 220 and the blue-light OLED device 230. The first sub-layer 321 is disposed on a side of the red-light OLED device 210 distal from the substrate 100; the second sub-layer 322 is disposed on a side of the green-light OLED device 220 distal from the substrate 100; and the third sub-layer 323 is disposed on a side of the blue-light OLED device 230 distal from the substrate 100.

In the second environment, at least partial region of the first sub-layer 321 is red, at least partial region of the second sub-layer 322 is green, and at least partial region of the third sub-layer 323 is blue, such that in the second environment, the first sub-layer 321 can act as a red filter, the second sub-layer 322 can act as a green filter, and the third sub-layer 323 can act as a blue filter.

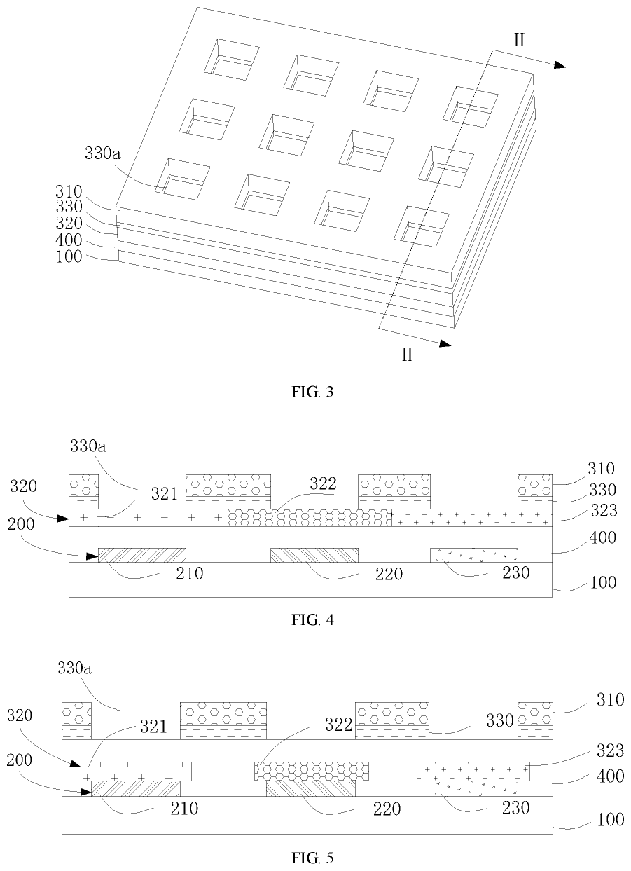

FIG. 3 is a schematic structural diagram of a display panel provided by an embodiment of the present disclosure. The display panel is a mirror display panel, which can not only function to display an image, but also can be used as a mirror. Therefore, such mirror display panel may be applied to fields such as home furnishing, shopping malls, advertising, beauty and cosmetics, and other fields such as car rearview mirrors, showing a promising prospect for further development.

FIG. 4 is a sectional view of II-II in FIG. 3. Compared with the display panel shown in FIG. 2, the display panel shown in FIG. 4 further includes a reflective layer 330 and a first film layer 310.

The reflective layer 330 is disposed on a side of the OLED device 200 distal from the substrate 100, and an orthographic projection of the reflective layer 330 onto the substrate 100 does not overlap with an orthographic projection of the OLED device 200 onto the substrate 100, that is, there is no overlapping region between the two orthographic projections.

The first film layer 310 is disposed on a side of the reflective layer 330 distal from the substrate 100, and an orthographic projection of the first film layer 310 onto the substrate 100 covers an orthographic projection of the reflective layer 330 onto the substrate 100.

In the first environment, the first film layer 310 is in a colorless and transparent state, and in the second environment, the first film layer 310 is in a black state.

In the case that the display panel is in the first environment, the first film layer 310 and the color film layer 320 are both in a transparent state, as such the light transmittance is high, and most of the light can be reflected by the reflective layer 330. In the case that the OLED device 200 does not emit light, the display panel may be used as a mirror. As such, in the case that the display panel is in the first environment, when the OLED device 200 emits light, due to the low intensity of the ambient light in the first environment, even if the first film layer 310 and the color film layer 320 are both in a colorless and transparent state, the reflected light generated by the reflective layer 330 and electrodes of the OLED device 200 is not obvious, and the display function of the display panel will not be effected. In the second environment, the first film layer 310 is in a black state and the ambient light is absorbed, so that the ambient light cannot be emitted to the reflective layer 330, thus no reflection will occur. The color film layer 320 is in a colored and transparent state, and a part of the ambient light is absorbed, so that the reflected light generated by the electrodes of the OLED device 200 is weakened. Under the combining effect of the first film layer 310 and the color film layer 320, the user can still view the picture displayed on the display panel effortlessly in an environment with relatively strong ambient light.

To facilitate the understanding of the present disclosure, the principles of the first film layer 310 and the color film layer 320 are explained below.

In an embodiment of the present disclosure, a material of the first film layer 310 is AgCl. AgCl is an unstable substance undergoing the following reaction:

Ag+Cl₂ [symbol] AgCl.

AgCl is in a colorless and transparent state, and has a relatively high light transmittance. Ag is black, and has a better light absorption effect, thereby the reflection of light can be reduced. Light irradiation will promote the reaction to the left direction, that is, promote the decomposition of AgCl. By using this reversible reaction, when the light intensity is changed, the first film layer 310 can realize the conversion between the colorless and transparent state and the black state. That is, the conversion of the first film layer 310 between the colorless and transparent state and the black state is achieved by virtue of this reaction.

The specific materials of the first sub-layer 321, the second sub-layer 322 and the third sub-layer 323 are not particularly limited, but can be any materials as long as the color film layer 320 can be effectively converted between the colorless and transparent state and the colored and transparent state when the light intensity is changed. According to some embodiments of the present disclosure, the material of the first sub-layer 321 can be a spironaphthopyran compound. The ring of the spironaphthopyran compound is opened under the irradiation of strong light, and a strong absorption will appear in the wavelength range of 380 nm to 550 nm (for example, blue light and green light), thus the first sub-layer 321 turns red, and acts as a red color filter. In the first environment, a C—O bond is formed, and the first sub-layer 321 is in a transparent state and has a better light transmittance. According to some embodiments of the present disclosure, the material of the second sub-layer 322 can be a spirooxazine derivative. The spirooxazine derivative has a strong absorption of blue light and red light under the irradiation of strong light, and then turns green and acts as a green color filter. In the first environment, the second sub-layer 322 is in a transparent state and has a better light transmittance. According to some embodiments of the present disclosure, the material of the third sub-layer 323 is a spiropyrane compound. Under the irradiation of strong light, the C—O bond in the molecule undergoes heterolysis, and a strong absorption appears in the wavelength range of 500 nm to 780 nm (for green light and red light). Thus, the third sub-layer 323 turns blue and acts as a blue color filter. In the first environment, the third sub-layer 323 is in a transparent state and has a better light transmittance.

According to some embodiments of the present disclosure, the materials for forming the first film layer 310, the first sub-layer 321, the second sub-layer 322, and the third sub-layer 323 are all stable in property and, can effectively ensure the occurrence of the above chemical reversible reaction under strong and weak light conditions during long-term use, such that the conversion between the colorless and transparent state and the colored state can be achieved and a long-term recycling use can be achieved. Therefore, the display panel has a relatively long service life.

In some specific embodiments of the present disclosure, the first film layer 310, the first sub-layer 321, the second sub-layer 322, and the third sub-layer 323 have a thickness of 1 to 5 micrometers, respectively. The first film layer 310, the first sub-layer 321, the second sub-layer 322, and the third sub-layer 323 may have a same thickness, or have different thicknesses. The thicknesses of the first film layer 310, the first sub-layer 321, the second sub-layer 322, and the third sub-layer 323 will affect their respective light absorption capabilities. A person skilled in the field can flexibly set the thickness of each layer according to actual requirements.

The specific material for constituting the reflective layer 330 is not particularly limited, as long as it has a good reflective capability. According to some embodiments of the present disclosure, a material of the reflective layer 330 is at least one of Al, Ag, or Mo. The reflective layer 330 has a relatively high reflectivity, which can enable the display panel to have a better mirror function. Also, the raw material has a wide range of source and a low cost.

According to some embodiments of the present disclosure, referring to FIG. 2 and FIG. 4, the display panel further include an encapsulating layer 400. The encapsulating layer 400 is disposed on a side of the OLED device 200 distal from the substrate 100 and configured to encapsulate the OLED device 200. The encapsulating layer 400 can provide protection for the OLED device 200 and prolong the service life of the display panel. The reflective layer 330 is disposed on a surface of the encapsulating layer 400 distal from the substrate 100, and an orthographic projection of the first film layer 310 onto the substrate 100 covers an orthographic projection of the reflective layer 330 onto the substrate 100. When the first film layer 310 switches between the black state and the colorless and transparent state upon the environment changes between the second environment and the first environment, the intensity of light emitted to the reflective layer 330 will correspondingly change, such that the display panel can realize the conversion between a normal display function and a mirror function.

According to some embodiments of the present disclosure, there is no special requirement on the detailed structure of the encapsulating layer 400, which can be flexibly designed by a person skilled in the field according to actual conditions. In some embodiments, in a direction of approaching the reflective layer 330, the encapsulating layer 400 includes a first inorganic layer, an organic layer, and a second inorganic layer that are sequentially stacked. The specific materials of the first inorganic layer and the second inorganic layer include but are not limited to silicon nitride, silicon oxide or silicon oxynitride. The above-mentioned materials have stable structures, can effectively block water and oxygen, which ensure a good encapsulating effect of the encapsulating layer. The organic layer is an ink layer, which has good flatness and helps to further improve an encapsulation effect of the encapsulating layer.

The display panel in the present disclosure may have diverse detailed structures. With reference to FIGS. 4 to 7, the specific structures of the mirror display panel of the present disclosure will be described in detail below based on some specific embodiments.

In some examples, the color film layer 320 is disposed in the encapsulating layer 400.

As shown in FIG. 5, the color film layer 320 is disposed on a side of the OLED device 200 distal from the substrate 100. Each of the first sub-layer 321, the second sub-layer 322, and the third sub-layer 323 is respectively disposed on a side, distal from the substrate 100, of the corresponding red-light OLED device 210, green-light OLED device 220, and blue-light OLED device 230, and covered by the encapsulating layer 400. The first film layer 310 is disposed on the surface of the reflective layer 330 distal from the substrate 100. In the second environment, the first sub-layer 321, the second sub-layer 322, and the third sub-layer 323 serve as color filters, and have a relatively high transmittance to the light emitted by the OLED device 200, and the display panel displays normally in the second environment. In the first environment, the first film layer 310, the first sub-layer 321, the second sub-layer 322, and the third sub-layer 323 are in a colorless and transparent state and have good light transmittance. When the OLED device 200 is not powered on, the display panel can be used as a mirror.

In some examples, the color film layer 320 is disposed on the surface of the encapsulating layer 400 distal from the substrate 100.

For example, as shown in FIG. 4, the color film layer 320 covers the surface of the encapsulating layer 400 distal from the substrate 100, and the reflective layer 330 is disposed on a side of the color film layer 320 distal from the substrate 100 and covers the surface of the color film layer 320.

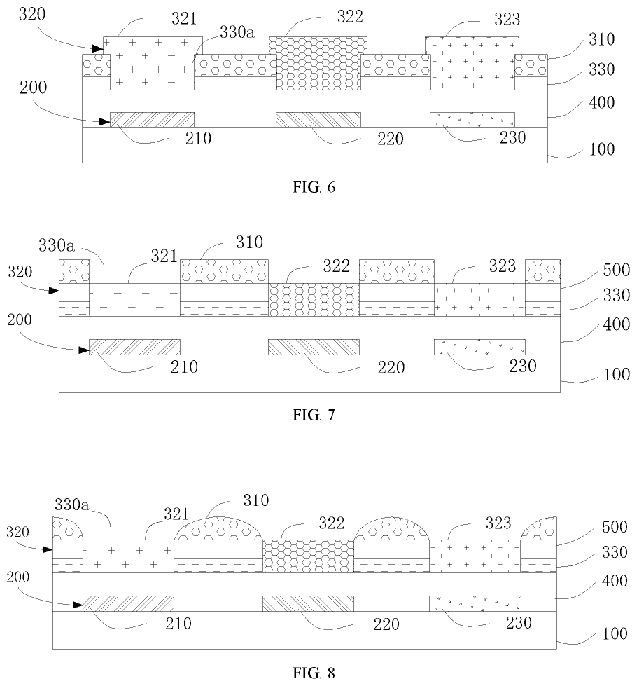

In another example, as shown in FIG. 6, in the display panel, the color film layer 320 and the reflective layer 330 are both disposed on the surface of the encapsulating layer 400 distal from the substrate 100. The first film layer 310 is disposed on the surface of the reflective layer 330 distal from the substrate 100.

The reflective layer 330 and the first film layer 310 define a plurality of openings 330a, in which the color film layer 320 is disposed. In addition, at least partial region of the color film layer 320 covers the surface of the first film layer 310 distal from the substrate 100. In some specific embodiments, the first sub-layer 321, the second sub-layer 322, and the third sub-layer 323 are disposed in the openings 330a, and at least partial region of each sub-layer covers the surface of the first film layer 310 distal from the substrate 100. In the second environment, the first sub-layer 321, the second sub-layer 322, and the third sub-layer 323 serve as color filters, which have a relatively high transmittance to the light emitted by the OLED device 200, and the display panel can display normally in the second environment. In the first environment, the first film layer 310, the first sub-layer 321, the second sub-layer 322, and the third sub-layer 323 are in a colorless and transparent state and have good light transmittance, which can realize a mirror function effectively.

As shown in FIG. 7, in this display panel, the reflective layer 330 and the first film layer 310 define a plurality of openings 330a. The color film layer 320 includes a first sub-layer 321, a second sub-layer 322, a third sub-layer 323 and a second film layer 500. The first sub-layer 321, the second sub-layer 322, and the third sub-layer 323 are disposed in the plurality of openings 330a, respectively. An orthographic projection of each of the first sub-layer 321, the second sub-layer 322, and the third sub-layer 323 onto the substrate 100 has no overlapping region with an orthographic projection of the first film layer 310 onto the substrate 100. The second film layer 500 is disposed on the surface of the reflective layer 330 distal from the substrate 100, and the first film layer 310 is disposed on the surface of the second film layer 500 distal from the substrate 100. The second film layer 500 is in a colorless and transparent state at least in the first environment.

In the second environment, the first sub-layer 321, the second sub-layer 322, and the third sub-layer 323 serve as color filters, and have a relatively high transmittance to the light emitted by the OLED device 200, and the display panel can display normally in the second environment. In the first environment, the first film layer 310, the first sub-layer 321, the second sub-layer 322, the third sub-layer 323 and the second film layer 500 are in a colorless and transparent state and have good light transmittance, which can realize a mirror function effectively.

The specific material for constituting the second film layer 500 is not particularly limited, as long as it is in a colorless and transparent state at least in the first environment. A material of the second film layer 500 is a transparent material or a color-changing material. For example, the second film layer 500 be made of a transparent material.

When the second film layer 500 is made of the color-changing material, the material of the second film layer 500 may be the same as that of the color film layer 320. In a case that the material of the second film layer 500 is the same as that of the color film layer 320, due to the weak ambient light in the first environment, the first film layer 310 is in a colorless and transparent state, and the second film layer 500 is also in a transparent state. In the second environment, the ambient light is relatively strong, and the first film layer 310 is in a black state. In this case, the light cannot arrive at the second film layer 500 due to blocking by the first film layer 310, thus the second film layer 500 is still in a colorless and transparent state.

In an exemplary embodiment, a part of the second film layer 500 close to a certain sub-layer has the same composition as that of the sub-layer. For example, the composition of the second film layer 500 between the first sub-layer 321 and the second sub-layer 322 may include a part made of spironaphthopyran compound and a part made of spirooxazine derivative, wherein the spironaphthopyran compound is disposed close to the first sub-layer 321, and the spirooxazine derivative is disposed close to the second sub-layer 322. In the first environment, the second film layer 500 is in a transparent state, which would still not affect the light reflectivity of the color film layer 320, thereby ensuring a good mirror effect.

A specific method for forming the color film layer in the present disclosure is not particularly limited. According to some embodiments of the present disclosure, the first film layer 310, the color film layer 320, and the reflective layer 330 can all be made through a patterning process. The patterning process refers to a process of photoresist coating, exposure, development, etching and stripping. Therefore, the display panel of the present disclosure can be prepared by using a developed and simple process to reduce the cost.

According to some embodiments of the present disclosure, referring to FIG. 8, the surface of the first film layer 310 distal from the substrate 100 is an arc-shaped convex surface. The arc-shaped convex surface protrudes in a direction away from the substrate 100. The first film layer 310 presents a morphology similar to a convex lens. Therefore, in the first environment, the first film layer 310 converges incident ambient light, so that more incident light may arrive at the reflective layer 330. Therefore, the display panel has a better mirror effect.

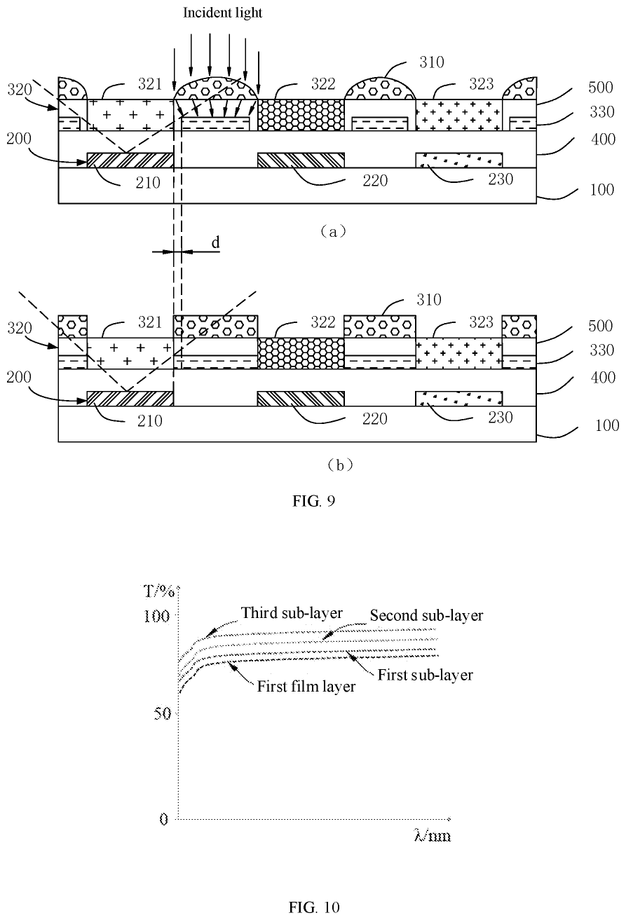

When the surface of the first film layer 310 distal from the substrate 100 is set as the arc-shaped convex surface, a size of the reflective layer 330 may be reduced to a certain extent. Referring to FIG. (a) in FIG. 9, an orthographic projection of the first film layer 310 onto the substrate 100 covers and is larger than the orthographic projection of the reflective layer 330 onto the substrate 100. In addition, there is a gap between the orthographic projection of the reflective layer 330 onto the substrate 100 and the orthographic projection of the light-emitting layer of the OLED device 200 onto the substrate 100, and a size of the gap is d. In FIG. 9, by comparing the FIG. (a) and FIG. (b), the surface of the first film layer 310 in FIG. (a) distal from the substrate 100 is the arc-shaped convex surface. The first film layer 310 converges the incident light, so that more light can arrive at the smaller reflective layer 330. That is, when reflecting light within a same range, the reflective layer 330 provided in FIG. (b) needs to have a larger size. It can be seen that, in a case that the surface of the first film layer 310 distal from the substrate 100 is set as the arc-shaped convex surface, when the light emitted by the OLED device 200 transmits through the openings 330a, a shielding range caused by the reflective layer 330 is smaller. Therefore, the light can arrive at a larger area, which increases a viewing angle of the display panel when it is displayed in the first environment.

According to some embodiments of the present disclosure, in the first environment, the display panel satisfies at least one of the following conditions: a light transmittance of the color film layer 320 is greater than 85%; or a light transmittance of the first film layer 310 is greater than 85%. As shown in FIG. 10, the x ordinate represents wavelength (λ/m), and the y ordinate represents wavelength transmittance (T/%). As such, the display panel can achieve a better mirror effect and can be used as a mirror.

According to some embodiments of the present disclosure, in the second environment, the display panel satisfies at least one of the following conditions: a light transmittance of the first film layer 310 at a wavelength of 380 nm to 780 nm is less than 2%; or a transmittance of the color film layer 320 to red light is greater than or equal to 50%, a transmittance of the color film layer 320 to green light is greater than or equal to 50%, and a transmittance of the color film layer 320 to blue light is greater than or equal to 50%.

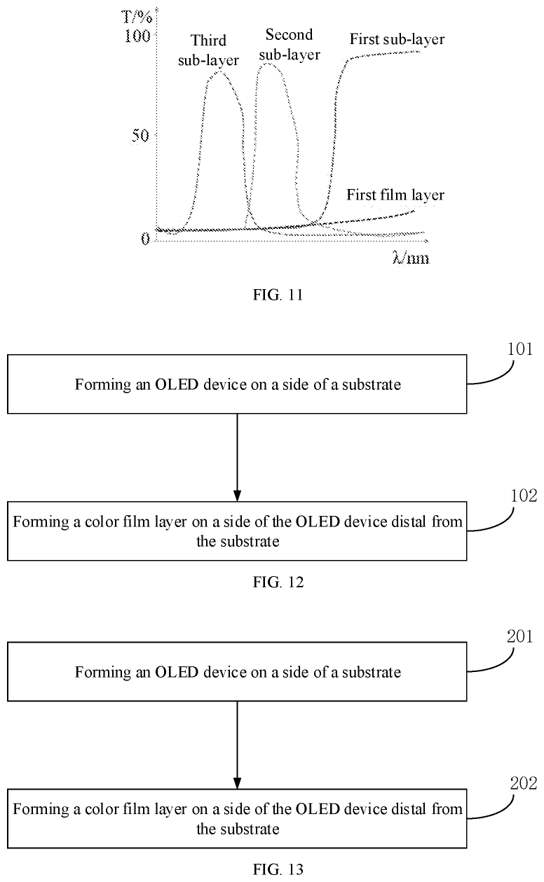

In some embodiments of the present disclosure, a transmittance of the first sub-layer 321 to red light is greater than or equal to 50%, a transmittance of the second sub-layer 322 to green light is greater than or equal to 50%, and a transmittance of the third sub-layer 323 to blue light is greater than or equal to 50%. In some specific embodiments, a graph showing the transmittance of the first sub-layer 321 to red light, the transmittance of the second sub-layer 322 to green light, and the transmittance of the third sub-layer 323 to blue light is provided in FIG. 11. The transmittance of the first sub-layer 321 to red light, the transmittance of the second sub-layer 322 to green light, and the transmittance of the third sub-layer 323 to blue light are greater than 80%, respectively, wherein the x ordinate represents wavelength (λ/m), and the y ordinate represents light transmittance (T/%). Therefore, the mirror display panel can realize a normal display function in the second environment.

FIG. 12 is a flowchart showing a method for manufacturing a display panel provided by an embodiment of the present disclosure. This method is used to manufacture the display panel shown in FIG. 1 or FIG. 2. As shown in FIG. 12, the method includes the following steps.

In step 101, an OLED device is formed on a side of a substrate.

In step 102, a color film layer is formed on a side of the OLED device distal from the substrate.

Referring to FIG. 2, an orthographic projection of the color film layer 320 onto the substrate 100 at least covers an orthographic projection of a light-emitting layer of the OLED device 200 onto the substrate 100. In a first environment, the color film layer 320 is in a colorless and transparent state; and in a second environment, at least partial region of the color film layer 320 is in a colored and transparent state, and a color of the region in the colored and transparent state is the same as a light-emitting color of the OLED device 200 covered by an orthographic projection of the region in the colored and transparent state onto the substrate 100. An ambient light luminance in the second environment is greater than an ambient light luminance in the first environment.

FIG. 13 is a flowchart showing a method for manufacturing a display panel provided by an embodiment of the present disclosure. This method is used to manufacture the display panel shown in any one of FIGS. 3 to 9 based on the method shown in FIG. 12. As shown in FIG. 13, the method includes the following steps.

In step 201, a reflective layer is formed on a side of the OLED device distal from the substrate.

An orthographic projection of the reflective layer onto the substrate does not overlap with an orthographic projection of the OLED device onto the substrate, that is, there is no overlapping region between two orthographic projections.

In step 202, a first film layer is formed on a side of the reflective layer distal from the substrate.

An orthographic projection of the first film layer onto the substrate covers an orthographic projection of the reflective layer onto the substrate. In the first environment, the first film layer is in a colorless and transparent state; and in the second environment, the first film layer is in a black state.

In the preparation of any of the display panels shown in FIGS. 3 to 5, step 201 is performed after step 102.

In the preparation of the display panel shown in FIG. 6, step 201 and step 202 are both performed after step 101 and before step 102.

In the preparation of any of the display panels shown in FIGS. 7 to 9, step 201 is performed after step 101 and before step 102, and step 202 is performed after step 102.

The manufacturing methods provided in the embodiments of the present disclosure are exemplary only. In actual manufacturing, other manufacturing methods may also be used, as long as the display panels mentioned in the embodiments of the present disclosure can be manufactured.

According to another aspect of the present disclosure, the present disclosure provides a display apparatus. The display apparatus includes a power supply component and the display panel shown in any one of FIGS. 1 to 9. The power supply component is configured to supply power to the display panel. Therefore, the display apparatus integrates all the features and advantages of the aforementioned display panels, which is not be repeated here. When the display apparatus includes the display panel as shown in FIG. 1 or FIG. 2, the display apparatus can realize a normal display function in the second environment. Therefore, the problem that the user cannot use a display function of the display apparatus due to the great stimulation to the human eyes caused by excessively strong reflected light in an outdoor strong light environment is solved. In addition, the display apparatus also has a favorable display function in the first environment. When the display device includes any of the display panels shown in FIGS. 3 to 9, the display apparatus also has a great mirror effect in the first environment, and can be used as a mirror.

According to some embodiments of the present disclosure, there is no special requirement on the specific type of the display apparatus, which can be flexibly designed by a person skilled in the field according to actual conditions. In some embodiments, specific types of the display apparatus include, but are not limited to, an electronic device having a display function, such as a mobile phone, iPad, a laptop, kindle, or a game console.

It can be understood by a person skilled in the field that, in addition to the aforementioned display panel, the display apparatus also has necessary structures or components of a conventional display apparatus. Taking a mobile phone as an example, in addition to the aforementioned display panel, the display apparatus further includes a touch panel, a housing, a CPU, an audio module, a camera module and other necessary structures and components.

When referring to a material of a layer in the embodiments of the present disclosure, it does not mean that the layer is only made of the mentioned material, but means that the material is included in the materials for manufacturing this layer, so as to utilize the properties of the mentioned material.

In the descriptions of the present specification, the orientation or position relations indicated via terms of “above”, “under”, and the like are based on orientation or the position relations shown in the drawings. They are merely for the purpose of being convenient to describe the present disclosure, but not to require that the present disclosure must be constructed and operated with the particular orientation, so that they should not be construed as limitations on the present disclosure.

In the descriptions of the present specification, the descriptions about reference terms such as “an embodiment”, “another embodiment”, “some embodiments”, “some specific embodiments” and the like mean that the specific features, structures, materials or characteristics described in combination with the embodiments are included in at least one embodiment of the present disclosure. In the present specification, the schematic descriptions of the above terms do not necessarily refer to a same embodiment or example. Furthermore, the specific features, structures, materials or characteristics as described can be integrated with any one or more embodiments or examples in a proper manner. In addition, a person skilled in the field can integrate and combine different embodiments or examples described in this specification and features of different embodiments or examples, as long as no contradiction occurs. Moreover, it should be noted that, the terms “first”, “second”, “third” and the like are only used for the purpose of description and should not be construed as indicating or implying relative importance or implicitly indicating the number of technical features as indicated.

Although the embodiments of the present disclosure have been shown and described above, it can be understood that the above embodiments are exemplary and should not be construed as limiting the present disclosure. A person of ordinary skill in the art can obtain changes, modifications, substitutions and variations to the above-mentioned embodiments within the scope of the present disclosure.

What is claimed is:

1. A display panel, comprising a substrate, an OLED device and a color film layer, wherein
the OLED device is disposed on a side of the substrate, and the color film layer is disposed on a side of the OLED device distal from the substrate;
an orthographic projection of the color film layer onto the substrate at least covers an orthographic projection of a light-emitting layer of the OLED device onto the substrate;
in a first environment, the color film layer is in a colorless and transparent state; in a second environment, at least partial region of the color film layer is in a colored and transparent state, and a color of the region in the colored and transparent state is the same as a light-emitting color of a target OLED device, the target OLED device being an OLED device covered by an orthographic projection of the region in the colored and transparent state onto the substrate; and an ambient light luminance in the second environment is greater than an ambient light luminance in the first environment.

2. The display panel according to claim 1, wherein the color film layer satisfies at least one of the following conditions:
in the first environment, a light transmittance of the color film layer is greater than 85%; or
in the second environment, a transmittance of the color film layer to red light is greater than or equal to 50% a transmittance of the color film layer to green light is greater than or equal to 50%, and a transmittance of the color film layer to blue light is greater than or equal to 50%.

3. The display panel according to claim 1, wherein the OLED device comprises a red-light OLED device, a green-light OLED device and a blue-light OLED device;
the color film layer comprises a first sub-layer, a second sub-layer and a third sub-layer, wherein the first sub-layer is disposed on a side of the red-light OLED device distal from the substrate; the second sub-layer is disposed on a side of the green-light OLED device distal from the substrate; and the third sub-layer is disposed on a side of the blue-light OLED device distal from the substrate; and
in the second environment, at least partial region of the first sub-layer is red, at least partial region of the second sub-layer is green, and at least partial region of the third sub-layer is blue.

4. The display panel according to claim 3, wherein a material of the first sub-layer is a spironaphthopyran compound, a material of the second sub-layer is a spirooxazine derivative, and a material of the third sub-layer is a spiropyran compound.

5. The display panel according to claim 1, further comprising a reflective layer and a first film layer, wherein
the reflective layer is disposed on a side of the OLED device distal from the substrate, and an orthographic projection of the reflective layer onto the substrate does not overlap an orthographic projection of the OLED device onto the substrate;
the first film layer is disposed on a side of the reflective layer distal from the substrate, and an orthographic projection of the first film layer onto the substrate covers an orthographic projection of the reflective layer onto the substrate; and
in the first environment, the first film layer is in a colorless and transparent state; and in the second environment, the first film layer is in a black state.

6. The display panel according to claim 5, wherein the reflective layer is disposed on a side of the color film layer distal from the substrate.

7. The display panel according to claim 5, wherein the reflective layer and the first film layer define a plurality of openings and the color film layer is disposed in the plurality of openings.

8. The display panel according to claim 5, wherein the color film layer is disposed on a side of the reflective layer distal from the substrate, and the first film layer is disposed on a side of the color film layer distal from the reflective layer.

9. The display panel according to claim 8, wherein a surface of the first film layer distal from the reflective layer is an arc-shaped convex surface.

10. The display panel according to claim 9, wherein the orthographic projection of the reflective layer onto the substrate is disposed within the orthographic projection of the first film layer onto the substrate; and there is a gap between the orthographic projection of the reflective layer onto the substrate and the orthographic projection of the OLED device onto the substrate.

11. The display panel according to claim 5, wherein the first film layer satisfies at least one of the following conditions:
in the first environment, a light transmittance of the first film layer is greater than 85%; or
in the second environment, a light transmittance of the first film layer at a wavelength of 380 nm to 780 nm is less than 2%.

12. The display panel according to claim 5, wherein a material of the first film layer is AgCl.

13. The display panel according to claim 5, wherein a material of the reflective layer is at least one of Al, Ag, or Mo.

14. The display panel according to claim 1, further comprising an encapsulating layer, which is disposed on a side of the OLED device distal from the substrate and configured to encapsulate the OLED device; and the color film layer is disposed in at least one of the following arrangements:
on a surface of the encapsulating layer distal from the substrate; and
inside the encapsulating layer.

15. A display apparatus, comprising a power supply component and a display panel, wherein the power supply component is configured to supply power to the display panel;
the display panel comprises a substrate, an OLED device and a color film layer;
the OLED device is disposed on a side of the substrate, and the color film layer is disposed on a side of the OLED device distal from the substrate;
an orthographic projection of the color film layer onto the substrate at least covers an orthographic projection of a light-emitting layer of the OLED device onto the substrate;
in a first environment, the color film layer is in a colorless and transparent state; in a second environment, at least partial region of the color film layer is in a colored and transparent state, and a color of the region in the colored and transparent state is the same as a light-emitting color of a target OLED device; the target OLED device being an OLED device covered by an orthographic projection of the region in the colored and transparent state onto the substrate; and an ambient light luminance in the second environment is greater than an ambient light luminance in the first environment.

16. The display apparatus according to claim 15, further comprising a reflective layer and a first film layer, wherein
the reflective layer is disposed on a side of the OLED device distal from the substrate, and an orthographic projection of the reflective layer onto the substrate does not overlap an orthographic projection of the OLED device onto the substrate;
the first film layer is disposed on a side of the reflective layer distal from the substrate, and an orthographic projection of the first film layer onto the substrate covers an orthographic projection of the reflective layer onto the substrate; and
in the first environment, the first film layer is in a colorless and transparent state; and in the second environment, the first film layer is in a black state.

17. The display apparatus according to claim 16, wherein the color film layer is disposed on a side of the reflective layer distal from the substrate, and the first film layer is disposed on a side of the color film layer distal from the reflective layer.

18. The display apparatus according to claim 17, wherein a surface of the first film layer distal from the reflective layer is an arc-shaped convex surface.

19. A method for manufacturing a display panel, comprising:
forming an OLED device on a side of a substrate; and
forming a color film layer on a side of the OLED device distal from the substrate, wherein an orthographic projection of the color film layer onto the substrate at least covers an orthographic projection of a light-emitting layer of the OLED device onto the substrate; in a first environment, the color film layer is in a colorless and transparent state; in a second environment, at least partial region of the color film layer is in a colored and transparent state, and a color of the region in the colored and transparent state is the same as a light-emitting color of a target OLED device, the target OLED device being an OLED device covered by an orthographic projection of the region in the colored and transparent state onto the substrate; and an ambient light luminance in the second environment is greater than an ambient light luminance in the first environment.

20. The method according to claim 19, further comprising:
forming a reflective layer on a side of the OLED device distal from the substrate, wherein an orthographic projection of the reflective layer onto the substrate does not overlap an orthographic projection of the OLED device onto the substrate; and
forming a first film layer on a side of the reflective layer distal from the substrate, wherein an orthographic projection of the first film layer onto the substrate covers an orthographic projection of the reflective layer onto the substrate; in the first environment, the first film layer is in a colorless and transparent state; and in the second environment, the first film layer is in a black state.
